(19) United States
(12) Patent Application Publication
(10) Pub. No.: US 2013/0224895 A1
(43) Pub. Date: Aug. 29, 2013

(54) CBD (CHEMICAL BATH DEPOSITION) FILM FORMATION APPARATUS AND METHOD FOR PRODUCING BUFFER LAYER

(71) Applicant: FUJIFILM Corporation, (US)

(72) Inventors: Tetsuo KAWANO, Kanagawa (JP); Hiroshi ARAI, Kanagawa (JP)

(73) Assignee: FUJIFILM Corporation, Tokyo (JP)

(21) Appl. No.: 13/861,714

(22) Filed: Apr. 12, 2013

Related U.S. Application Data
(63) Continuation of application No. PCT/JP2011/005712, filed on Oct. 12, 2011.

(30) Foreign Application Priority Data
Oct. 12, 2010 (JP) 229251/2010
Oct. 12, 2010 (JP) 229252/2010
Oct. 12, 2010 (JP) 229253/2010

(51) Int. Cl. H01L 31/18

(52) U.S. Cl. CPC H01L 31/18
USPC 438/57; 118/68; 118/428

(57) ABSTRACT

A support-heat unit that supports and heats a substrate from the back side of the substrate, a reaction bath having an opening for supplying a CBD reaction solution for forming a film onto a front surface of the substrate, which is supported by the support-heat unit, and a reaction bath forward-backward drive unit that can press the opening onto the front surface of the substrate by moving the reaction bath toward the front surface of the substrate, which is supported by the support-heat unit, and that can detach the opening from the front surface of the substrate by moving the reaction bath away from the front surface of the substrate are provided.

### BACKGROUND OF THE INVENTION

1. Field of the Invention

The present invention relates to a CBD film formation apparatus appropriate for formation of buffer layers of CI (G)S-based solar cells, or the like. Further, the present invention relates to a method for producing a photoelectric conversion device using the CBD film formation apparatus, or a method for producing a buffer layer constituting the photoelectric conversion device.

2. Description of the Related Art

A photoelectric conversion device including a photoelectric conversion layer and an electrode electrically connected to the photoelectric conversion layer is used for various purposes, such as solar cells. Conventionally, the main trend of solar cells was Si-based solar cells using bulk monocrystalline Si or polycrystalline Si, or a thin film of amorphous Si. However, research and development of compound semiconductor-based solar cells that do not rely on Si is being carried out. As the compound semiconductor-based solar cells, a bulk system, such as GaAs system, and a thin film system, such as CIS or CIGS system composed of a group Ib element, a group IIIb element, and a group VIb element, are well known. CI(G)S is a compound semiconductor represented by the general formula of Cu_{1-z}In₁₋ₓGaₓSe_{2-y}S_{y} (in the formula, 0≦x≦1, 0≦y≦2, and 0≦z≦1), and the formula represents a CIS system when x=0, and a CIGS system when x>0. Hereinafter, CIS and CIGS will be collectively represented as “CI(G)S”.

Generally, in conventional thin film system photoelectric conversion devices, such as CI(G)S systems, a CdS buffer layer or a ZnS buffer layer, which does not contain Cd in consideration of environmental burden, is provided between a photoelectric conversion layer and a transparent conductive layer (transparent electrode) formed on the photoelectric conversion layer. The role of the buffer layer is (1) prevention of recombination of photogenerated carriers, (2) alignment of band discontinuity, (3) lattice matching, (4) coverage of the unevenness of a surface of the photoelectric conversion layer, and the like. In CI(G)S system, and the like, the degree of the unevenness of the surface of the photoelectric conversion layer is relatively large. Therefore, it is necessary to efficiently satisfy, especially, the aforementioned condition (4). Hence, deposition by using a CBD (Chemical Bath Deposition) method, which is a liquid phase method, is desirable.

In the CBD method, a so-called batch-type deposition method, in which a substrate is immersed in a reaction solution containing the material compound of a buffer layer, is known. For example, Japanese Patent No. 4443645 (Patent Document 1) discloses a CBD deposition apparatus that can improve the evenness of a deposited film, and reduce the size of the reaction bath, and the like. The CBD deposition apparatus keeps a surface on which a film is to be formed by CBD in such a manner that the surface is horizontal to the reaction bath and faces the upper side, and an oscillator is driven. Further, Japanese Patent No. 4080061 (Patent Document 2) discloses an apparatus including oscillators arranged at equidistance on a wall of a reaction bath. The apparatus holds an object on which a CBD film is to be formed in such a manner that the object is vertical to the reaction bath.

Meanwhile, a method for continuously performing deposition is also known, and a so-called roll-to-roll (Roll to Roll) deposition method is known. The roll-to-roll method uses a supply roll formed by winding a long flexible substrate in roll form and a winding roll for winding the substrate after deposition in roll form. In this method, while the substrate is sent from the supply roll and the substrate after deposition is wound on the winding roll synchronously, it is possible to carry out deposition on the conveyed substrate in the reaction bath continuously or in a stop-and-go manner. For example, specification of U.S. Patent Application Publication No. 20090246908 (Patent Document 3) discloses a mode of collecting a reaction solution to suppress a loss of a material for forming a buffer layer (a reaction solution) due to deposition of a film on wall surfaces of a reaction bath, or the like. Further, specification of U.S. Patent Application Publication No. 20090255461 (Patent Document 4) discloses a similar mode.

### SUMMARY OF THE INVENTION

In the batch type, as disclosed in Patent Documents 1 and 2, in which the substrate is immersed in the CBD solution, when the substrate includes a portion that is dissolvable in the CBD solution (including, for example, cases in which a dissolvable component is exposed on edge surfaces of the substrate, the back side of the substrate, and the like), it is impossible to adopt the known CBD method. Meanwhile, the roll-to-roll deposition method disclosed in Patent Documents 3 and 4 is desirable to improve the productivity. However, it is impossible to continuously carry out the CBD method while the edge surfaces and the back side of the substrate are protected.

In view of the foregoing circumstances, it is an object of the present invention to provide a CBD film formation apparatus that can perform CBD film formation without dissolving a substrate even if the substrate includes a portion that is dissolvable in the CBD solution. Further, it is another object of the present invention to provide a method for producing a photoelectric conversion device using the CBD film formation apparatus, or a method for producing a buffer layer constituting the photoelectric conversion device.

A CBD film deposition apparatus according to a first aspect of the present invention is a CBD film formation apparatus comprising:

a support-heat unit that supports and heats a substrate from the back side of the substrate;

a reaction bath having an opening for supplying a CBD reaction solution for forming a film onto a front surface of the substrate, which is supported by the support-heat unit; and

a reaction bath forward-backward drive unit that can press the opening onto the front surface of the substrate by moving the reaction bath toward the front surface of the substrate, which is supported by the support-heat unit, and that can detach the opening from the front surface of the substrate by moving the reaction bath away from the front surface of the substrate.

It is desirable that the support-heat unit supports the substrate from the upper side of the substrate, and that the reaction bath is arranged on the lower side of the substrate, and moved toward the front surface of the substrate from the lower side of the substrate and away from the front surface of the substrate.

It is desirable that the reaction bath includes a reaction solution supply channel for supplying the reaction solution into the reaction bath and a reaction solution discharge channel for discharging the reaction solution in the reaction bath.

It is desirable that the substrate is a flexible substrate, and that the apparatus includes a roll core on which the flexible substrate is wound, and a substrate conveyance unit that supplies the substrate to the support-heat unit by intermittently drawing the substrate from a substrate roll formed by winding the flexible substrate on the roll core.

It is desirable that a plurality of reaction baths are provided, and that the plurality of reaction baths are simultaneously movable toward the substrate and away from the substrate.

The substrate may contain a metal that can form a hydroxide ion and a complex ion.

The substrate may be one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

A method for producing a buffer layer according to the first aspect of the present invention is a method for producing a buffer layer by using a CBD method in a photoelectric conversion device having a layered structure including a lower electrode, a photoelectric conversion semiconductor layer that generates an electric current by absorption of light, the buffer layer, and a transparent conductive layer on a substrate, the method for producing the buffer layer comprising the steps of:

supplying the substrate to a support-heat unit that supports and heats the substrate from the back side of the substrate, and heating the substrate from the back side of the substrate; and

moving, with respect to the heated substrate, a reaction bath having an opening for supplying a CBD reaction solution for forming the buffer layer toward a front surface of the substrate, which is supported by the support-heat unit, and pressing the opening onto the front surface of the substrate to deposit the buffer layer on a surface of the photoelectric conversion semiconductor layer provided on the substrate.

A method for producing a photoelectric conversion device according to the first aspect of the present invention is a method for producing a photoelectric conversion device having a layered structure including a lower electrode, a photoelectric conversion semiconductor layer that generates an electric current by absorption of light, a buffer layer, and a transparent conductive layer on a substrate, wherein the buffer layer is produced by using a CBD method, and the method for producing the photoelectric conversion device comprising the steps of:

supplying the substrate to a support-heat unit that supports and heats the substrate from the back side of the substrate, and heating the substrate from the back side of the substrate; and

moving, with respect to the heated substrate, a reaction bath having an opening for supplying a CBD reaction solution for forming the buffer layer toward a front surface of the substrate, which is supported by the support-heat unit, and pressing the opening onto the front surface of the substrate to deposit the buffer layer on a surface of the photoelectric conversion semiconductor layer provided on the substrate.

A CBD film formation apparatus according a second aspect of the present invention is a CBD film formation apparatus comprising:

a drum that supports a long substrate in close contact with the long substrate;

a reaction bath filled with a CBD reaction solution for immersing therein a part of the drum, which supports the long substrate in close contact with the long substrate;

protection members that protect edges on lateral direction sides of the long substrate, which is supported by the drum in close contact with the drum, and portions of the drum that are not in close contact with the long substrate from the CBD reaction solution by overlapping with the edges on the lateral direction sides and the portions of the drum; and

a drive unit that makes the long substrate, which is in close contact with the drum, and the protection members run together in the CBD reaction solution in such a manner to be matched with the peripheral velocity of the drum.

It is desirable that the drum includes a heating means that heats the long substrate, which is supported by the drum in close contact with the drum.

It is desirable that the drum can magnetically support the long substrate in close contact with the long substrate.

It is desirable that the surface of the CBD reaction solution in the reaction bath is located at a lower position than positions at which the long substrate and the protection members overlapping with the long substrate start contacting with each other.

The long substrate may contain a metal that can form a hydroxide ion and a complex ion.

The long substrate may be one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

It is desirable that the long substrate includes a lower electrode and a photoelectric conversion semiconductor layer that generates an electric current by absorption of light.

A method for producing a photoelectric conversion device according to the second aspect of the present invention is a method for producing a photoelectric conversion device having a layered structure including a buffer layer and a transparent conductive layer on a photoelectric conversion semiconductor layer of a long substrate including a lower electrode and the photoelectric conversion semiconductor layer that generates an electric current by absorption of light, wherein the buffer layer is formed by making a drum support the long substrate in such a manner that the drum is in close contact with the long substrate and that a photoelectric conversion semiconductor layer side surface of the long substrate is positioned on the front surface side of the long substrate, and by making protection members overlap with edges on lateral direction sides of the long substrate, which is supported by the drum in close contact with the drum, and portions of the drum that are not in close contact with the long substrate, and by immersing, in a reaction solution for forming the buffer layer in a reaction bath, a part of the drum, which supports the long substrate in close contact with the long substrate.

A method for producing a buffer layer according to a third aspect of the present invention is a method for producing a buffer layer by using a CBD method in a photoelectric conversion device having a layered structure including a lower electrode, a photoelectric conversion semiconductor layer that generates an electric current by absorption of light, the buffer layer, and a transparent conductive layer on a substrate, the method for producing the buffer layer comprising the steps of:

fixing the substrate at an opening that is provided on a wall of a reaction bath for CBD, and the size of the opening being less than the size of the substrate, in such a manner to cover the whole opening with the substrate from the outside of the reaction bath; and

depositing the buffer layer in a region of a surface of the photoelectric conversion semiconductor layer provided on the substrate, and the region facing the opening.

It is desirable that the substrate is heated from the back side of the substrate.

The reaction solution may be stirred.

The reaction solution contains, for example, a metal source of Cd or Zn and a sulfur source.

A buffer layer production apparatus according to the third aspect of the present invention is a buffer layer production apparatus that forms, on a photoelectric conversion semiconductor layer formed on a substrate, a buffer layer by using a CBD method, the apparatus comprising:

a reaction bath that can store a reaction solution for CBD to form the buffer layer;

an opening formed on a wall of the reaction bath, and the size of the opening being less than the size of the substrate; and

a holding unit that can hold the substrate on an outer surface of the wall of the reaction bath at a position corresponding to the opening in such a manner to cover the whole opening with the substrate.

It is desirable that a heating means that can heat the substrate from the back side of the substrate is further provided.

It is desirable that the reaction bath is made of a material that is both alkali-resistant and acid-resistant.

The reaction bath may include a stirring means that stirs the reaction solution.

The substrate may contain a metal that can form a hydroxide ion and a complex ion.

The substrate may be one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

A method for producing a photoelectric conversion device according to the third aspect of the present invention is a method for producing a photoelectric conversion device having a layered structure including a lower electrode, a photoelectric conversion semiconductor layer that generates an electric current by absorption of light, a buffer layer, and a transparent conductive layer on a substrate, wherein the buffer layer is produced by using a CBD method, the method for producing the photoelectric conversion device comprising the steps of:

fixing the substrate at an opening that is provided on a wall of a reaction bath for CBD, and the size of the opening being less than the size of the substrate, in such a manner to cover the whole opening from the outside of the reaction bath; and

depositing the buffer layer in a region of a surface of the photoelectric conversion semiconductor layer provided on the substrate, and the region facing the opening.

The CBD film formation apparatus according to the first aspect of the present invention includes a support-heat unit that supports and heats a substrate from the back side of the substrate, a reaction bath having an opening for supplying a CBD reaction solution for forming a film onto a front surface of the substrate, which is supported by the support-heat unit, and a reaction bath forward-backward drive unit that can press the opening onto the front surface of the substrate by moving the reaction bath toward the front surface of the substrate, which is supported by the support-heat unit, and that can detach the opening from the front surface of the substrate by moving the reaction bath away from the front surface of the substrate. Therefore, even if the substrate contains an element that is dissolvable in the reaction solution for CBD, it is possible to form a film without dissolving such an element from the substrate.

Further, in the CBD film formation apparatus according to the first aspect of the present invention, when the substrate is a flexible substrate, and the apparatus includes a roll core on which the flexible substrate is wound, and a substrate conveyance unit that supplies the substrate to the support-heat unit by intermittently drawing the substrate from a substrate roll formed by winding the flexible substrate on the roll core, a film is formable by so-called roll-to-roll. Therefore, continuous formation of the film is possible.

The CBD film formation apparatus according to the second aspect of the present invention includes a drum that supports a long substrate in close contact with the long substrate, a reaction bath filled with a CBD reaction solution for immersing therein a part of the drum, which supports the long substrate in close contact with the long substrate, protection members that protect edges on lateral direction sides of the long substrate, which is supported by the drum in close contact with the drum, and portions of the drum that are not in close contact with the long substrate from the CBD reaction solution by overlapping with the edges on the lateral direction sides and the portions of the drum, and a drive unit that makes the long substrate, which is in close contact with the drum, and the protection members run together in the CBD reaction solution in such a manner to be matched with the peripheral velocity of the drum. Therefore, even if the substrate contains an element that is dissolvable in the reaction solution for CBD, it is possible to perform CBD deposition without dissolving such an element from the substrate.

In the method for producing a buffer layer according to the third aspect of the present invention, the substrate is fixed at an opening that is provided on a wall of a reaction bath for CBD, and the size of the opening being less than the size of the substrate, in such a manner to cover the whole opening with the substrate from the outside of the reaction bath, and the buffer layer is deposited in a region of a surface of the photoelectric conversion semiconductor layer provided on the substrate, and the region facing the opening. Therefore, even if the substrate contains an element that is dissolvable in the reaction solution for CBD, it is possible to form the buffer layer without dissolving such an element from the substrate.

Further, in the method for producing a buffer layer according to the third aspect of the present invention, the substrate is fixed at an opening provided on a wall of a reaction bath, and the buffer layer is deposited. Therefore, when the method is compared with an ordinary batch-type mode, in which buffer layers are deposited on substrates standing in the reaction bath, an influence of a difference in temperature is small. Hence, it is possible to form a buffer layer the thickness of which is substantially even.

### BRIEF DESCRIPTION OF THE DRAWINGS

FIG. 1 is a schematic diagram illustrating an embodiment of a CBD film formation apparatus according to a first aspect of the present invention;

FIG. 2 is a schematic diagram illustrating another embodiment of the CBD film formation apparatus according to the first aspect of the present invention;

FIG. 3 is an enlarged schematic diagram illustrating a reaction bath in the CBD film formation apparatus according to the first aspect;

FIG. 4 is a schematic oblique diagram illustrating an embodiment of a CBD film formation apparatus according to a second aspect of the present invention;

FIG. 5 is a schematic cross section illustrating the CBD film formation apparatus illustrated in FIG. 4;

FIG. 6 is a schematic cross section illustrating an embodiment of protection members that protect a long substrate in the CBD film formation apparatus according to the second aspect;

FIG. 7 is a schematic cross section illustrating another embodiment of protection members that protect a long substrate in the CBD film formation apparatus according to the second aspect;

FIG. 8 is a schematic cross section illustrating still another embodiment of protection members that protect a long substrate in the CBD film formation apparatus according to the second aspect;

FIG. 9 is a schematic cross section illustrating still another embodiment of protection members that protect a long substrate in the CBD film formation apparatus according to the second aspect;

FIG. 10A is a schematic cross section illustrating still another embodiment of protection members that protect a long substrate in the CBD film formation apparatus according to the second aspect;

FIG. 10B is a schematic cross section illustrating still another embodiment of protection members that protect a long substrate in the CBD film formation apparatus according to the second aspect;

FIG. 11A is a schematic cross section illustrating still another embodiment of protection members that protect a long substrate in the CBD film formation apparatus according to the second aspect;

FIG. 11B is a schematic cross section illustrating still another embodiment of protection members that protect a long substrate in the CBD film formation apparatus according to the second aspect;

FIG. 12 is a schematic cross section illustrating still another embodiment of protection members that protect a long substrate in the CBD film formation apparatus according to the second aspect;

FIG. 13 is a schematic diagram illustrating an embodiment of a buffer layer production apparatus according to a third aspect of the present invention;

FIG. 14 is an enlarged cross section at line I-I in FIG. 13;

FIG. 15 is a schematic diagram illustrating an embodiment in which a heating means is provided in the production apparatus according to the third aspect;

FIG. 16A is a schematic cross section illustrating the structure of an anodized substrate;

FIG. 16B is a schematic cross section illustrating the structure of an anodized substrate; and

FIG. 17 is a graph illustrating the distribution of the thicknesses of buffer layers produced in examples according the third aspect.

### DESCRIPTION OF THE PREFERRED EMBODIMENTS

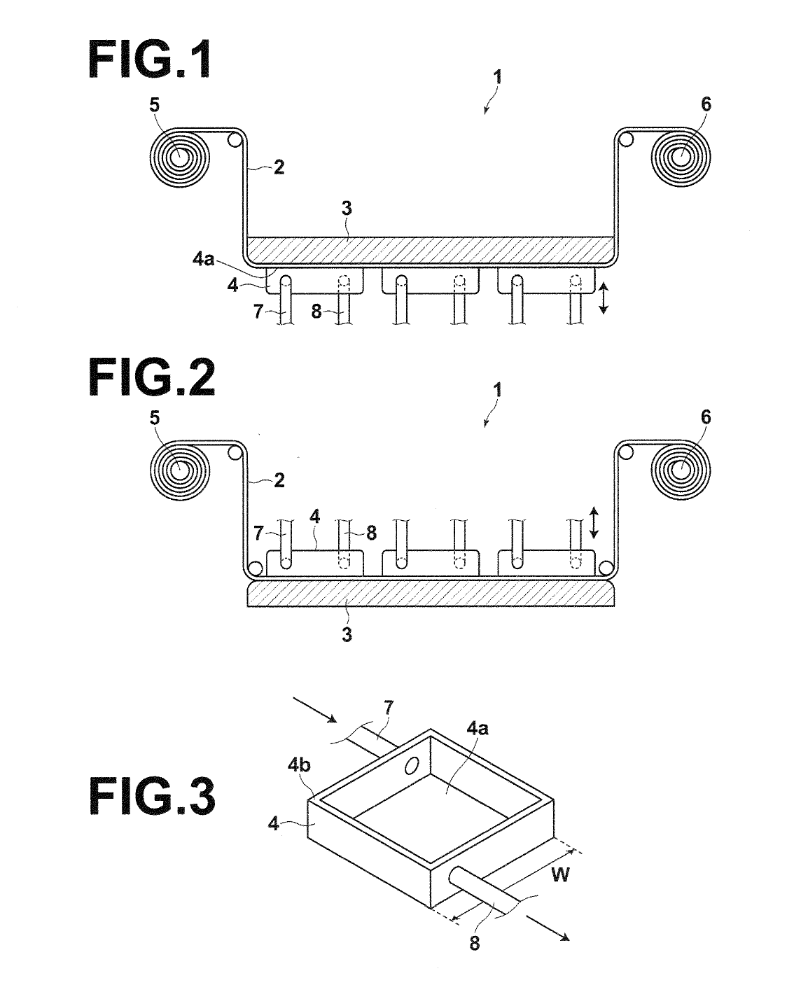

Hereinafter, a CBD film formation apparatus according to a first aspect of the present invention will be described with reference to drawings. FIG. 1 is a schematic diagram illustrating an embodiment of the CBD film formation apparatus according to the first aspect of the present invention. A CBD film formation apparatus 1 illustrated in FIG. 1 includes a support-heat unit 3 that supports and heats a substrate 2 from the back side of the substrate 2, a reaction bath 4 having an opening 4a for supplying a CBD reaction solution for forming a film onto a front surface of the substrate 2, which is supported by the support-heat unit 3, and a reaction bath forward-backward drive unit (not illustrated, and hereinafter, also referred to as a drive unit) that can press the opening 4a onto the front surface of the substrate 2 by moving the reaction bath 4 toward the front surface of the substrate 2, which is supported by the support-heat unit 3, and that can detach the opening 4a from the front surface of the substrate 2 by moving the reaction bath 4 away from the front surface of the substrate 2.

The support-heat unit 3 illustrated in FIG. 1 supports the substrate 2 from the upper side of the substrate 2. The reaction bath 4 is arranged on the lower side of the substrate 2, and moved toward the front surface of the substrate 2 from the lower side and away from the front surface of the substrate 2. As illustrated in FIG. 2, the support-heat unit 3 may support the substrate 2 from the lower side of the substrate 2. Further, the reaction bath 4 may be arranged on the upper side of the substrate 2, and moved toward the front surface of the substrate 2 from the upper side and away from the front surface of the substrate 2. In FIG. 2, the same numbers are assigned to elements similar to those of FIG. 1. The substrate 2 illustrated in FIG. 1 is a flexible substrate.

The substrate 2 is wound on a roll core 5, and a substrate conveyance unit is provided. The substrate conveyance unit supplies the substrate 2 to the support-heat unit 3 by intermittently drawing the substrate 2 from a substrate roll formed by winding the substrate 2 on the roll core 5. In FIG. 1, the substrate conveyance unit is connected to a roll core 6 on which the substrate 2 after deposition is to be wound (not illustrated).

Here, a case in which the substrate is a flexible substrate is described, as an example. Alternatively, the substrate may be a cut substrate, and when the substrate is a cut-sheet type, it is not necessary that the substrate is flexible. FIG. 1 illustrates a mode in which three reaction baths 4 are provided. The number of the set reaction baths 4 may be more than three. Further, although the productivity is lowered, the number of the set reaction bath may be one. When plural reaction baths 4 are provided, the plural reaction baths 4 are simultaneously movable toward the substrate and away from the substrate.

With reference to FIG. 3, the structure of the reaction bath 4 will be described in detail. As described above, the reaction bath 4 includes the opening 4a for supplying a CBD reaction solution for forming a film onto a front surface of the substrate 2. Further, the reaction bath 4 includes a reaction solution supply channel 7 for supplying the reaction solution into the reaction bath 4 and a reaction solution discharge channel 8 for discharging the reaction solution in the reaction bath 4. The reaction bath 4 is structured in such a manner that the reaction solution is supplied to the reaction bath 4 from the reaction solution supply channel 7 after the reaction bath 4 has been moved by a drive unit toward a front surface of the substrate 2, which is supported by the support-heat unit 3, and the opening 4a is pressed onto the front surface of the substrate 2.

Reversely, the reaction bath 4 is structured in such a manner that the reaction solution in the reaction bath 4 is discharged through the reaction solution discharge channel 8 before the reaction bath 4 is moved away from the front surface of the substrate 2 and the opening 4a is detached from the front surface of the substrate 2. While the reaction solution is supplied to the reaction bath 4 from the reaction solution supply channel 7, the reaction solution discharge channel 8 also functions to allow air in the reaction bath 4 to escape therefrom. Further, when the reaction bath 4 is filled with the reaction solution until the reaction solution reaches the opening 4a of the reaction bath 4, an excessive amount of reaction solution is discharged from the reaction solution discharge channel 8. The reaction solution supply channel 7 is controlled in such a manner that supply of the reaction solution can be stopped by detecting such a state.

A pressing surface 4b of the opening 4a of the reaction bath 4, which is pressed onto the substrate 2, is formed in such a manner that the reaction solution does not leak into the reaction bath 4 when the pressing surface 4b is pressed onto the substrate 2. For example, the pressing surface 4b is made of silicon. Further, width W of the reaction bath 4 is narrower than the lateral width of the substrate 2. Therefore, the reaction bath 4 is attachable and detachable without touching any edge on a lateral direction side of the substrate 2. Since the reaction bath 4 is structured in such a manner, even if the substrate contains an element that is dissolvable in the CBD reaction solution, it is possible to form a film without dissolving such an element from edge surfaces of the substrate.

Next, the operation of the CBD film formation apparatus according to the first aspect of the present invention, illustrated in FIG. 1, will be described. Here, a case of producing a buffer layer in a photoelectric conversion device having a layered structure including a lower electrode, a photoelectric conversion semiconductor layer that generates an electric current by absorption of light, the buffer layer, and a transparent conductive layer on a substrate will be described, as an example. The substrate conveyance unit supplies the substrate 2 to the support-heat unit 3 by intermittently drawing the substrate 2 (here, the substrate means the whole layered structure of a photoelectric conversion device including a substrate, a lower electrode, and a photoelectric conversion semiconductor layer deposited one on another in this order). At this time, the substrate 2 is supplied in such a manner that the substrate in the photoelectric conversion device is located on the support-heat unit 3 side of the substrate 2, and that the photoelectric conversion semiconductor layer is located on the reaction bath 4 side of the substrate 2.

The substrate 2 supplied to the support-heat unit 3 is heated by the support-heat unit 3 from the back side of the substrate 2, in other words, from the substrate side of the photoelectric conversion device. The drive unit is driven, and the reaction bath 4 for supplying the CBD reaction solution for forming the buffer layer is moved, with respect to the heated substrate 2, toward a front surface of the substrate 2, which is supported by the support-heat unit 3. Specifically, the reaction bath 4 is moved toward the surface of the photoelectric conversion semiconductor layer, and the opening 4a is pressed onto the surface of the photoelectric conversion semiconductor layer of the substrate 2.

When the opening 4a of the reaction bath 4 is pressed onto the surface of the photoelectric conversion semiconductor layer, supply of the reaction solution from the reaction solution supply channel 7 to the reaction bath 4 is started. When supply of the reaction solution is started, first, air in the reaction bath 4 is discharged from the reaction solution discharge channel 8. However, when the reaction solution has filled the reaction bath 4 to reach the front surface of the substrate 2, the reaction solution is discharged from the reaction solution discharge channel 8. When the discharge amount is detected as an excessive amount of reaction solution after the reaction solution has reached the front surface of the substrate 2, the reaction solution supply channel 7 and the reaction solution discharge channel 8 are closed. Then, the buffer layer is deposited on the surface of the photoelectric conversion semiconductor layer of the substrate 2.

The reaction solution touches only the surface of the photoelectric conversion semiconductor layer of the substrate 2, on which the buffer layer is to be deposited. Therefore, even if the substrate contains an element that is dissolvable in the reaction solution for CBD, it is possible to form the buffer layer without dissolving such an element from the substrate. Further, since it is possible to form the film on the front surface of the substrate 2 using a minimum amount of reaction solution for forming the film, it is possible to reduce the amount of reaction solution used in one film formation operation, compared with the case of the batch method. Therefore, it is possible to reduce the amount of waste reaction solution produced by film formation. Hence, an environmental merit is obtainable.

Further, it is possible to form a buffer layer the thickness of which is substantially even, because the substrate is heated by the support-heat unit 3 from the back side of the substrate and the size of the reaction bath 4 does not substantially induce a difference in temperature within the reaction bath 4, compared with the batch method. In this case, it is desirable that the temperature of the substrate is the same as, or higher than the solution temperature of the reaction solution for CBD. If the temperature of the substrate is higher than or equal to the solution temperature of the reaction solution for CBD, the progress of deposition on the substrate precedes. At this time, if deposition on the substrate progresses even if the temperature of the reaction solution is lowered, formation of a colloidal solid material in the reaction solution tends to be suppressed. Therefore, it is possible to continue using the reaction solution for a long period of time. Further, if the supplied reaction solution is always new, it is possible to form a buffer layer the thickness of which is substantially more even, and the composition of which is even. Further, as illustrated in FIG. 1, film formation by so-called roll-to-roll is possible. Therefore, continuous formation of the film is possible.

When the buffer layer is formed, a colloidal solid material adheres to the surface of the buffer layer in some cases. If the colloidal solid material is kept in such a manner, it becomes impossible to maintain high resistance in a portion coated with the buffer layer, and to improve the conversion efficiency of solar cells. Therefore, it is normally necessary to remove the colloidal solid material through a washing process, or the like. However, when the support-heat unit 3 supports the substrate 2 from the upper side of the substrate 2, and the reaction bath 4 is arranged on the lower side of the substrate 2, as illustrated in FIG. 1, it is possible to suppress adhesion of the colloidal solid material to some extent during deposition of the buffer layer. In the case of the reaction apparatus illustrated in FIG. 2, it is desirable that the colloidal solid material that has been adhered to the surface of the buffer layer is removed through a washing process, or the like.

When a buffer layer having a desirable thickness is deposited, the reaction solution in the reaction bath 4 is discharged from the reaction solution discharge channel 8. Here, the reaction solution that has been used once may be disposed of, but it may be used again as long as the unevenness of thickness and composition is acceptable. After the reaction solution is discharged, the drive unit is driven, and the opening 4a is detached from the front surface of the substrate 2 by moving the reaction solution 4 away from the front surface of the substrate 2. Then, the substrate conveyance unit moves the substrate to the position of the next reaction bath. As in this case, when there are plural reaction baths, deposition of the buffer layer is performed plural times corresponding to the number of the reaction baths by using a stop-and-go method.

Normally, after the buffer layer is formed on the substrate, it is necessary to rinse the buffer layer, and to dry the buffer layer. FIG. 1 illustrates a mode in which the substrate on which the buffer layer has been formed is wound on the roll core 6. Alternatively, a mode of performing processes including the washing and drying steps after formation of the buffer layer, as in-line processes, may be adopted. Further, the heating step after formation of the buffer layer, which will be described later, may also be included the in-line processes.

It is desirable that a substrate before formation of the buffer layer is preheated. As preheating, the substrate may be heated by hot dry air. Alternatively, a heater may be used to heat the substrate. For example, a heating unit for heating the substrate by hot dry air during conveyance of the substrate from the roll core 5 to the support-heat unit 3 may be provided separately. Needless to say, normally, an adhered object that adheres to the surface of the photoelectric conversion semiconductor layer is washed and removed before formation of the buffer layer. In this case, a washing process should be performed before the substrate is heated by hot dry air, or heated by using a heater. Alternatively, a solution (pure water, an ammonia solution, a lower amine solution, or the like) for removing the adhered object may be heated, and an adhered object removal process and a substrate preheat process may be performed at the same time on the substrate before the substrate is wound on the roll core 5.

As described above, it is possible to form the buffer layer by using the CBD film formation apparatus according to the first aspect of the present invention. The CBD film formation apparatus according to the first aspect of the present invention may be appropriately used not only to form the buffer layer, as described above, but also to perform CBD film formation, such as formation of a thin film of a metal oxide or a metal oxide doped with a specific element, or the like.

When the buffer layer is made of ZnS, or Zn(S, O), or Zn(S, O, OH), as will be described later, after formation of the buffer layer, post-heating is performed at a temperature of 150° C. to 230° C., and preferably at a temperature of 170° C. to 210° C., for 5 minutes to 60 minutes. A heating means is not particularly limited, but it is desirable to heat by an oven, an electric furnace, a vacuum oven, or the like that is on the market. Needless to say, in-line heating equipment may be used for heating. When a heating process is performed in this manner, it is possible to improve the characteristic of the photoelectric conversion device, such as a conversion efficiency. This feature is similar also in a second aspect, which will be described next.

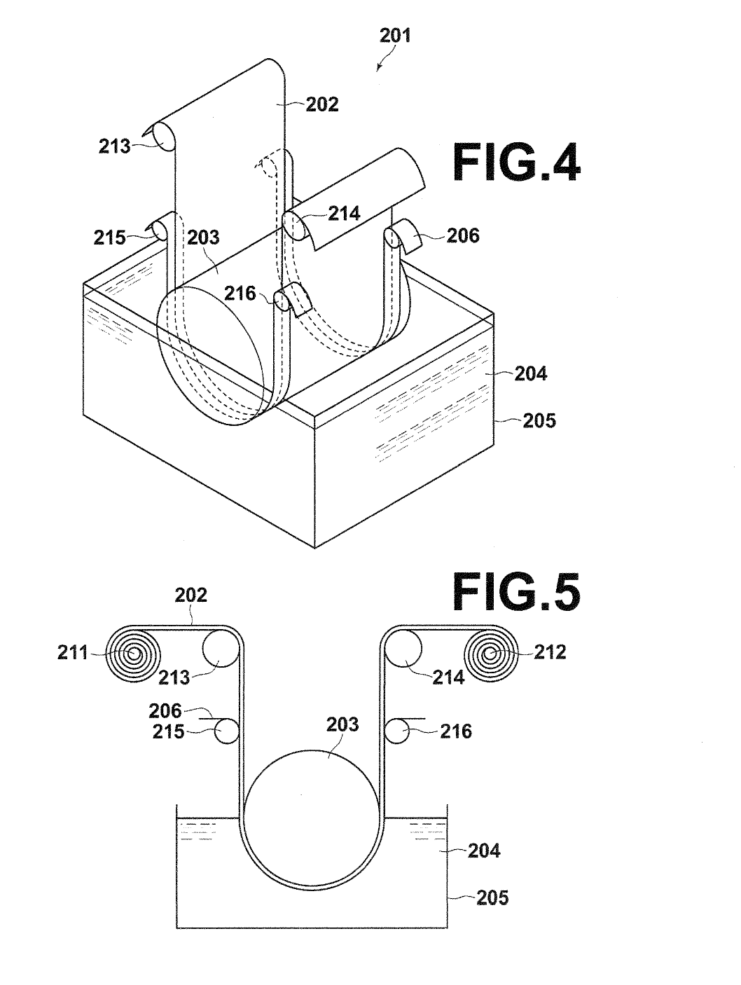

Next, a CBD film formation apparatus according to the second aspect of the present invention will be described. FIG. 4 is a schematic oblique diagram illustrating an embodiment of a CBD film formation apparatus according to the second aspect of the present invention. FIG. 5 is a schematic cross section illustrating the CBD film formation apparatus illustrated in FIG. 4. In FIG. 4, a reaction bath is illustrated as a transparent reaction bath. A CBD film formation apparatus 201 illustrated in FIGS. 4 and 5 includes a drum 203 that supports a long substrate 202 in close contact with the long substrate 202, a reaction bath 205 filled with a CBD reaction solution 204 for immersing therein a part of the drum 203, which supports the long substrate 202 in close contact with the long substrate 202, protection members 206 that protect edges on lateral direction sides of the long substrate 202, which is supported by the drum 203 in close contact with the drum 203, and portions of the drum 203 that are not in close contact with the long substrate 202 from the CBD reaction solution 204 by overlapping with the edges on the lateral direction sides and the portions of the drum, and a drive unit (not illustrated) that makes the long substrate 202, which is in close contact with the drum 203, and the protection members 206 run together in the CBD reaction solution 204 in such a manner to be matched with the peripheral velocity of the drum 203.

Further, an unwinding roll 211 on which the long substrate 202 is wound in roll form is provided on the upstream side of the drum 203, and a winding roll 212 on which the long substrate 202 after formation of a CBD thin film on one side of the long substrate 202 is to be wound is provided on the downstream side of the drum 203. Further, a delivery roll 213 is provided between the unwinding roll 211 and the drum 203, and a delivery roll 214 is provided between the winding roll 212 and the drum 203. Further, an unwinding roll or rolls 215 on which the protection members 206 are wound in roll form are provided between the drum 203 and the delivery roll 213, and a winding roll or rolls 216 on which the protection members 206 are to be wound are provided between the drum 203 and the delivery roll 214. Further, the protection members 206 that are sent from the unwinding roll or rolls 215 can overlap with edges on lateral direction sides of the long substrate 202 and portions of the drum 203 that are not in close contact with the long substrate 202. Further, drives (not illustrated) are provided for the winding rolls 212 and 216, respectively, and it is possible to make the long substrate 202, which is in close contact with the drum 203, and the protection members 206 run together in the CBD reaction solution 204 in such a manner to be matched (synchronously) with the peripheral velocity of the drum 203.

Here, a mode in which the drives provided for the winding rolls 212 and 216 drive the winding rolls 212 and 216, respectively, and the long substrate 202 after formation of the CBD thin film and the protection members 206 are wound on the winding rolls 212 and 216, respectively, is described. Alternatively, the winding rolls 212 and 216 may be structured just in a rotatable manner, and have only functions of sending the long substrate 202 and the protection members 206. Further, winding rolls controlled by other respective drives may be arranged on the downstream side of the winding rolls 212 and 216. Meanwhile, the drum 203, itself, is structured just in a rotatable manner, and the drives as described above are driven to make the drum 203 convey the long substrate 202 while only one of surfaces of the long substrate 202 is immersed in the CBD reaction solution 204. Alternatively, a drive source may be provided for the drum 203, and the drum 203, itself, may rotate.

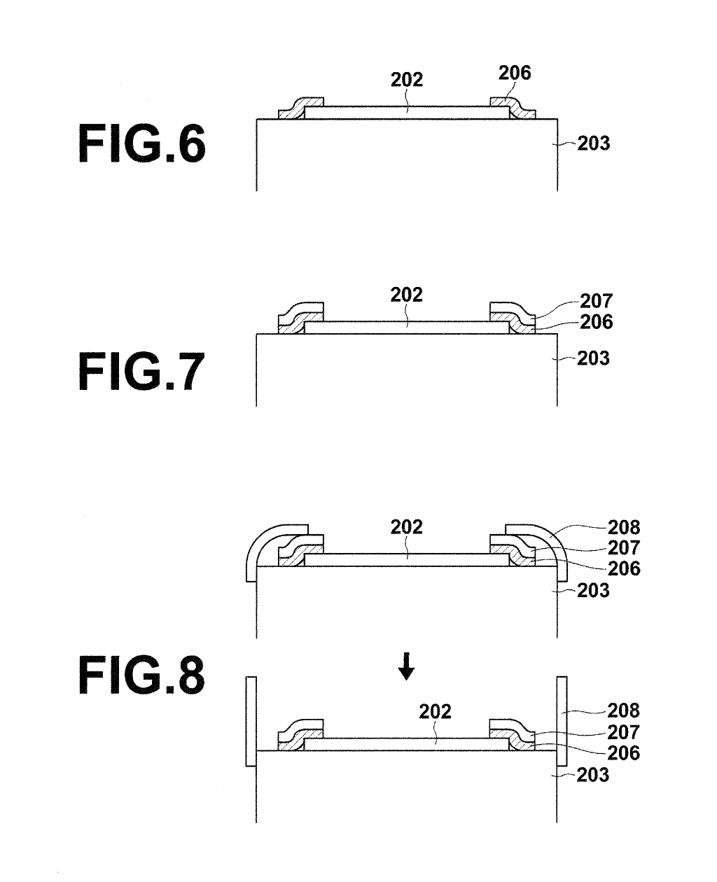

FIG. 6 is a schematic cross section illustrating an embodiment of protection members that protect a long substrate. As illustrated in FIG. 6, the protection members 206 can overlap with edges on lateral direction sides of the long substrate 202 and portions of the drum 203 that are not in close contact with the long substrate 202. Since the protection members 206 overlap in this manner, the CBD reaction solution 204 does not enter and touch the back side of the long substrate 202 (a side in close contact with the drum 203) and the edge surfaces of the long substrate 202. Therefore, even if the long substrate 202 contains an element dissolvable in the CBD reaction solution, it is possible to form the CBD thin film without dissolving such an element from the long substrate 202.

It is desirable that the protection members 206 are made of a material, such as a Viton rubber and a silicone rubber, to secure close contact with the long substrate 202. Alternatively, even if the whole protection members 206 are not made of such a material, an adhesive material may be applied at least to sides of the protection members 206, and the sides being in close contact with the long substrate 202.

To improve the watertightness between the long substrate 202 and the protection members 206 that overlap with the long substrate 202, it is desirable that the drum 203 is structured in such a manner that the drum 203 can magnetically support the long substrate in close contact with the long substrate 202. For example, a permanent magnet having magnetic properties as itself, and which can attract a magnetic material, such as iron, may be arranged in the drum 203, and especially at a portion in close contact with the long substrate 202. Then, if the long substrate 202 is a magnetic material, it is possible to magnetically support the long substrate 202 in close contact with the drum 203.

Further, even if the long substrate 202 is not made of a magnetic material, if metal plates 207 made of magnetic material (magnetic metal plates, for example, such as SUS316) are further overlapped on the protection members 206, as illustrated in FIG. 7, it is possible to magnetically support the long substrate 202 in close contact with the drum 203 in a similar manner (in FIG. 7, the same numbers are assigned to the same composition elements as those of FIG. 6, and explanations on such elements are omitted unless particularly necessary (hereinafter, the same also for the other figures)). In this case, as illustrated in FIG. 8, the metal plates 207 may be fixed by presser springs 208. Here, the presser springs 208 are provided at plural positions around the entire circumference of the drum 203. The presser springs 208 are controlled in such a manner that the presser springs 208 press the metal plates 207 from the upper sides of the metal plates 207, as illustrated in the upper diagram of FIG. 8, in a portion of the drum 203 immersed in the reaction solution, and that the presser springs 208 move away from the metal plates 207, as illustrated in the lower diagram of FIG. 8, after the drum 203 leaves the reaction solution.

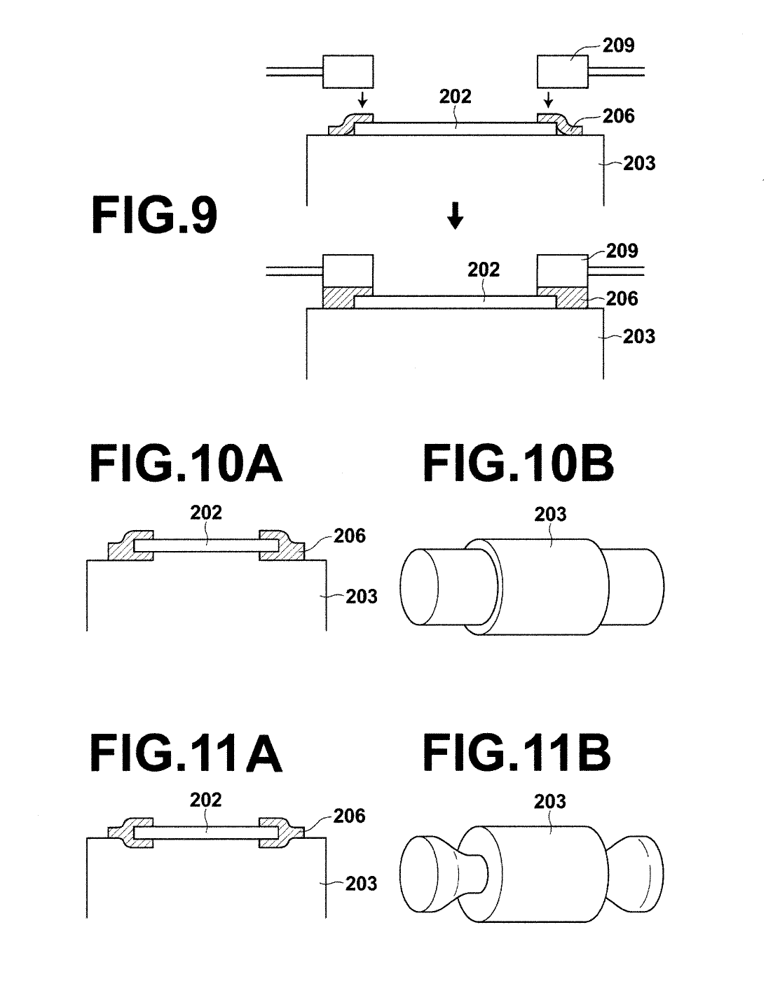

Alternatively, as illustrated in FIG. 9, pressure drums 209 for pressuring the protection members 206 onto the drum 203 may be provided. It is desirable that pressure drums 209 are provided at plural positions facing the drum 203 immersed in the reaction solution.

It is desirable that the drum 203 includes a heating means that heats the long substrate 202, which is supported in close contact, from the back side of the long substrate 202. Normally, the reaction solution for CBD is heated, and reacts. If the long substrate 202 is heated from its back side, it is possible to form a film the thickness of which is more even. In this case, it is desirable that the temperature of the substrate is the same as the solution temperature of the reaction solution for CBD, or higher. If the temperature of the substrate is higher than or equal to the solution temperature of the reaction solution for CBD, the progress of deposition on the substrate precedes. At this time, when deposition on the substrate progresses even if the temperature of the reaction solution is lowered, formation of a colloidal solid material in the reaction solution tends to be suppressed. Therefore, it is possible to continue using the reaction solution for a long period of time. As heating means, a mode of providing a heater in the drum 203, a mode of circulating a heated medium (for example, water or oil) in the drum, and the like are desirable.

In the above descriptions, a case in which the long substrate 202 is protected by the protection members 206 that have been unwound from the unwinding roll or rolls 215 before the long substrate 202 is immersed in the reaction solution 204 and the protection members 206 are wound on the winding roll or rolls 216 after the long substrate 202 moves out from the reaction solution 204 was described as an example. Alternatively, the protection members 206 maybe provided, in advance, on the long substrate 202 that is wound on the winding roll 211 in roll form. For example, as illustrated in FIGS. 10A and 11A, the protection members 206 may protect edges on lateral direction sides of the long substrate 202 from both sides of the long substrate 202. In this case, as illustrated in FIGS. 10A and 10B, a portion of the drum 203 to be in close contact with the long substrate 202 may be projected to secure the watertightness between the long substrate 202 and the protection members 206 that overlap with the long substrate 202. Alternatively, as illustrated in FIGS. 11A and 11B, a portion of the drum 203 to be in close contact with the long substrate 202 may be projected, and depression portions may formed, in advance, at portions of the drum 203 on which the protection members 206 run to prevent meandering of the long substrate 202.

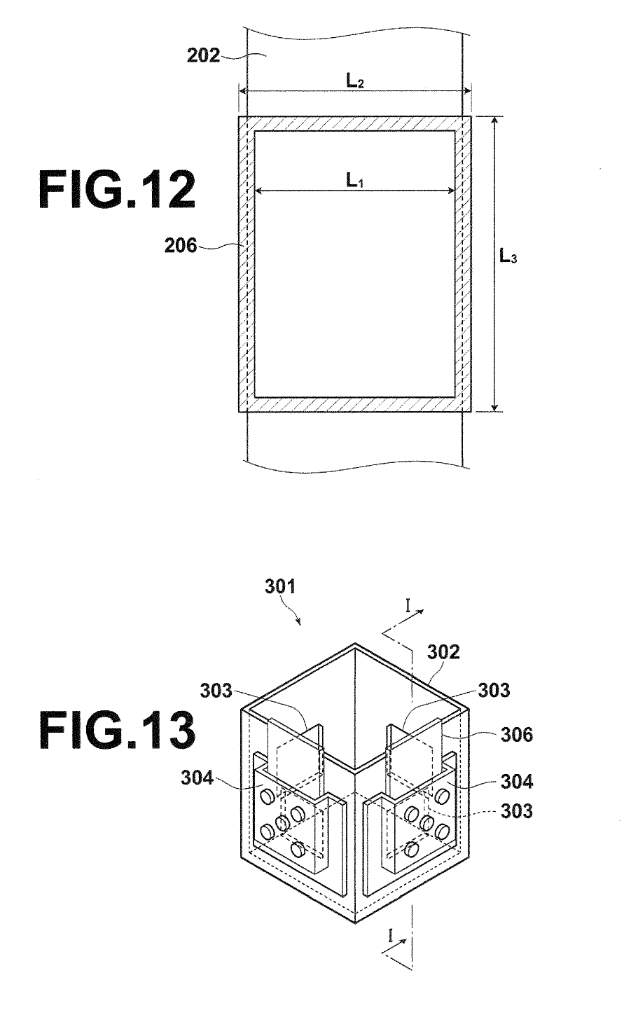

Alternatively, plural protection members 206, as illustrated in FIG. 12, may be arranged in advance through the entire length of the long substrate 202 that is would on the unwinding roll 211 in roll form. Here, FIG. 12 illustrates a state in which one protection member 206 is arranged so that the arrangement of the protection member 206 is easily identifiable. In this case, L₁<Width of Long Substrate<L₂, and L₂≦Width of Drum. In this case, it is desirable that L₃ of the protection member 206 is less than or equal to the circumference of the drum.

Next, with reference to FIGS. 4 and 5, the operation of the CBD film formation apparatus according to the second aspect of the present invention will be described. Here, a case in which the long substrate includes a lower electrode and a photoelectric conversion semiconductor layer that generates electric current by absorption of light, and a buffer layer is formed on the photoelectric conversion semiconductor layer by using a CBD method will be described, as an example. First, a long substrate 202 that is wound in roll form is sent from the unwinding roll 211, and supported by the drum 203 in close contact with the drum 203. After then, the long substrate 202 is wound on the winding roll 212. At this time, the long substrate 202 is wound in such a manner that the photoelectric conversion semiconductor layer faces outside. Similarly, protection members 206 that are wound in roll form are sent from the unwinding roll or rolls 215, and wound on the winding roll or rolls 216.

The protection members 206 overlap with edges on lateral direction sides of the long substrate 202, which is supported by the drum 203 in close contact with the drum 203, and portions of the drum 203 that are not in close contact with the long substrate 202 so that the CBD reaction solution 204 does not touch the back surface and the edge surfaces of the long substrate 202. In this state, a part of the drum 203, for example, a part to the center of the drum 203 is immersed in the CBD reaction solution 204 in the reaction bath 205. At this time, the surface of the CBD reaction solution 204 in the reaction bath 205 should be located at a lower position than positions at which the long substrate 202 and the protection members 206 overlapping with the long substrate 202 start contacting with each other.

Here, a drive is driven, and the long substrate 202, which is in close contact with the drum 203, and the protection members 206 run together in the CBD reaction solution 204 synchronously with the peripheral velocity of the drum 203. Accordingly, a buffer layer is formed on one of surfaces of the long substrate 202 that is not in close contact with the drum 203, in other words, on the surface of the photoelectric conversion semiconductor layer. The reaction solution touches only the surface of the photoelectric conversion semiconductor layer of the long substrate 202 on which the buffer layer is to be deposited. Therefore, even if the substrate contains an element that is dissolvable in the reaction solution for CBD, it is possible to form the buffer layer without dissolving such an element from the substrate. Further, the CBD reaction solution 204 does not enter the back side of the long substrate 202 (a side in close contact with the drum 203). Therefore, it is possible to prevent formation of the buffer layer on the back side of the long substrate 202.

When the buffer layer is formed, a colloidal solid material adheres to the surface of the buffer layer in some cases. If the colloidal solid material is kept in such a state, it becomes impossible to maintain high resistance in a portion coated with the buffer layer, and to improve the conversion efficiency of solar cells. Therefore, it is normally necessary to remove the colloidal solid material by a washing process, or the like. Therefore, normally, after the buffer layer is formed, it is necessary to wash, rinse and dry the buffer layer. FIG. 5 illustrates a mode in which the substrate on which the buffer layer has been formed is wound on the winding roll 212. Processes including the washing step, the rinsing step and the drying step after formation of the buffer layer may be performed as in-line processes. Further, the heating step after formation of the buffer, which will be described later, may be included in the in-line processes.

It is desirable that a substrate before formation of the buffer layer is preheated. As preheating, the substrate may be heated by hot dry air, or heated by a heater. For example, a heating unit for heating the substrate by hot dry air during conveyance of the substrate from the unwinding roll 211 to the drum 203 may be provided separately. Needless to say, an adhered object that adheres to the surface of the photoelectric conversion semiconductor layer is normally washed and removed from the surface before formation of the buffer layer. In this case, a washing process should be performed before the substrate is heated by hot dry air, or heated by using a heater. Alternatively, a solution (pure water, an ammonia solution, a lower amine solution, or the like) for removing the adhered object may be heated, and an adhered object removal process and a substrate preheat process may be performed at the same time on the substrate before the substrate is wound on the unwinding roll 211.

As described above, it is possible to form the buffer layer. The CBD film formation apparatus according to the second aspect of the present invention may be appropriately used not only to form the buffer layer, as described above, but also to perform CBD film formation, such as formation of a thin film of a metal oxide or a metal oxide doped with a specific element, or the like.

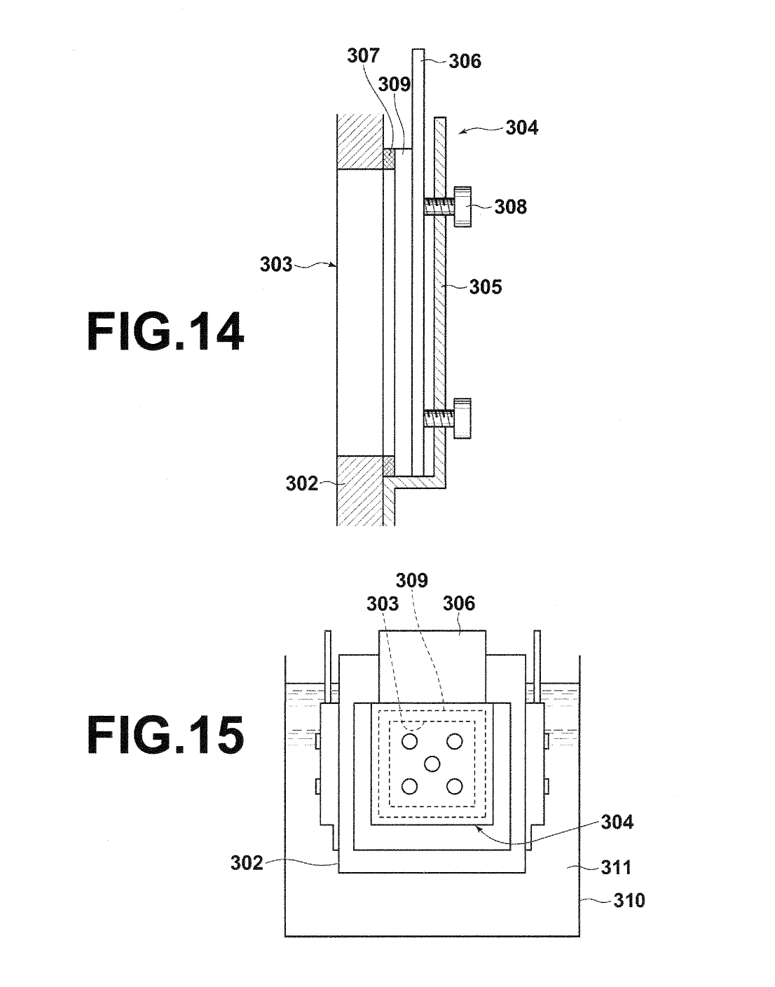

Next, a method for producing a buffer layer according to a third aspect of the present invention will be described. FIG. 13 is a schematic diagram illustrating an embodiment of a buffer layer production apparatus according to the third aspect of the present invention. FIG. 14 is an enlarged cross section at line I-I in FIG. 13. In a production apparatus 301 illustrated in FIG. 13, openings 303 are provided on four walls of a reaction bath 302 in which the reaction solution for CBD for forming the buffer layer can be stored. Further, a holding unit 304 that can hold a substrate 309 in such a manner to cover the whole opening 303 with the substrate 309 is provided at a position corresponding to the opening 303 on the outer surface of the wall of the reaction bath 302. In FIG. 13, a mode in which the holding units 304 are provided on two front walls of the reaction bath 302 is illustrated so as to be easily identifiable.

As illustrated in FIG. 14, the inside of the holding unit 304 is composed of a substrate holder 305, a back plate 306 that can evenly pressure the entire back side of the substrate 309, a gasket (packing) 307 provided between the substrate 309 and the wall surface of the reaction bath 302, and a screw member 308 that can pressure the substrate holder 305 toward the opening 303. The substrate holder 305 is structured in such a manner that the substrate 309 placed in the substrate holder 305 abuts the bottom of the substrate holder 305. Further, the opening 303 is smaller than the size of the substrate 309.

Further, the substrate 309 is fixed, by the screw member 308 directed to the substrate holder 305, at a position corresponding to the opening 303 in such a manner that the substrate 309 covers the whole opening 303. At this time, the substrate 309 completely closes the opening 303 of the reaction bath 302 by the gasket 307. Therefore, even if the reaction bath 302 is filled with the reaction solution, the reaction solution does not leak from the reaction bath 302. Further, since the back plate 306 can protect the substrate 309 from a local pressure applied by the screw member 308, the substrate 309 does not deform. Here, a mode in which the gasket 307 is provided in advance on the outer surface of the wall of the reaction bath 302 is described. However, it is not always necessary that the gasket 307 is provided on the outer surface of the wall of the reaction bath 302. The gasket 307 may be provided on the substrate 309 side to match the outer edge of the substrate 309. As the material of the gasket 307, Teflon (Registered Trademark, hereinafter, this description will be omitted in the specification of the present application), a sheet-shaped Teflon (as a product on the market, for example, product name: Hyper-Sheet), a silicon rubber, a Viton rubber, and the like are desirable.

As described, in the production apparatus according to the third aspect of the present invention, the back side (the back surface) of the substrate and the side surfaces of the substrate do not touch the reaction solution. Therefore, even if the substrate contains an element that is dissolvable in the reaction solution for CBD, it is possible to form the buffer layer without dissolving such an element from the substrate. Further, for example, when deposition is performed on plural substrates standing in the reaction vessel, a difference in the temperature of the reaction solution is generated between a portion close to the wall surface of the reaction vessel and a central portion of the vessel. Therefore, there is a problem that the thickness of the layer formed on the substrate close to the wall surface of the reaction vessel and the thickness of the layer formed on the substrate in the central portion of the reaction vessel are not uniform. However, in the production apparatus according to the third aspect of the present invention, since the substrates are fixed to the walls, it is possible to form buffer layers the thickness of which are uniform.

It is desirable that the production apparatus according to the third aspect of the present invention further includes a heating means that can heat the substrate from the back side of the substrate. Normally, the reaction solution for CBD is heated to be used. If the substrate is heated from the back side of the substrate, it is possible to form a buffer layer the thickness of which is more even. In this case, it is desirable that the temperature of the substrate is the same as the solution temperature of the reaction solution for CBD, or higher. If the temperature of the substrate is higher than or equal to the solution temperature of the reaction solution for CBD, the progress of deposition on the substrate precedes. At this time, when deposition on the substrate progresses even if the temperature of the reaction solution is lowered, formation of a colloidal solid material in the reaction solution tends to be suppressed. Therefore, it is possible to continue using the reaction solution for a long period of time. An example of the heating means is a mode of providing a bath 310 for a heating liquid that can store a heating liquid 311 around the reaction bath 302, as illustrated in FIG. 15. As the heating liquid, heating water, oil or the like may be used, and heating water is desirable from operational view points. In this case, it is desirable that the back plate 306 is a plate made of a high thermal conductivity material, specifically, such as titanium and stainless steel. Further, when the back plate 306 is a metal plate made of a material, for example, such as titanium, a mode of heating by winding an electric heating instrument (heater) on the back plate 306 is adoptable. Here, a material, such as a silicon rubber sheet, may be placed between the back side of the substrate and the back plate 306 to prevent a scratch caused by direct contact between the back side of the substrate and the back plate 306.

It is desirable that the substrate used for the buffer layer is preheated. As preheating, the substrate may be heated by hot dry air, or heated by a heater. Needless to say, an adhered object that adheres to a surface is normally washed and removed before formation of the buffer layer. In this case, a wash process should be performed before the substrate is heated by hot dry air, or heated by using a heater. Alternatively, a solution (pure water, an ammonia solution, a lower amine solution, or the like) for removing the adhered object may be heated, and an adhered object removal process and a substrate preheat process may be performed at the same time.

It is desirable that the reaction bath 302 is made of a material that is both alkali-resistant and acid-resistant. Normally, it is sufficient if the material of the reaction bath is not corroded by the reaction solution (an alkali-resistant material when the CBD method is used). However, when the buffer layer is formed by using the CBD method, a colloidal solid material adheres to the inner surface of the reaction bath or the like in some cases. If the CBD process is repeated while this colloidal solid material is kept, the layer accumulated on the inner wall acts as a seed crystal layer, and a growth of a thin film on the inner wall precedes. Consequently, it becomes impossible to achieve good regeneration characteristics in formation of a thin film on a desirable substrate. Therefore, normally, it is necessary to wash the inside of the reaction bath at a certain frequency with an acid solution that can dissolve the colloidal solid material. If the reaction bath 302 is made of a material that is both alkali-resistant and acid-resistant, it is possible to perform the wash process also in this production apparatus after formation of the buffer layer. As the material that is both alkali-resistant and acid-resistant, for example, Teflon is desirable. Further, even if a base, itself, is stainless steel, or the like, a mode of coating, with Teflon, a portion that will touch the reaction solution may be adopted.

A stirring means for stirring the reaction solution may be provided in the reaction bath 302. If the stirring means for stirring the reaction solution is provided, it is possible to make the surface of the photoelectric conversion semiconductor layer of the substrate that is fixed on the wall of the reaction bath 302 constantly touch a fresh reaction solution. Hence, it is possible to reduce the deposition time. A desirable example of the stirring means is a stirring means using a magnetic stirrer that is rotated magnetically.

After formation of the buffer layer, the reaction solution is discarded, and the substrate in which the buffer layer has been formed on the photoelectric conversion semiconductor layer is detached from the substrate holder. When the buffer layer is made of ZnS, or Zn(S, O), or Zn(S, O, OH), as will be described later, post-heating is performed at a temperature of 150° C. to 230° C., and preferably at a temperature of 170° C. to 210° C., for 5 minutes to 60 minutes. A heating means is not particularly limited, but it is desirable to heat with hot air by an oven, an electric furnace, a vacuum oven, or the like that is on the market. It is possible to improve characteristics of the photoelectric conversion device, such as a conversion efficiency, by performing the heating process in this manner.

The CBD method according to the first through third aspects of the present invention is a method in which a crystal is deposited on a substrate at an appropriate speed in a stable environment by forming complexes of metal ion M using, as a reaction solution, a metal ion solution having a concentration and pH that induce supersaturation by an equilibrium represented by a general formula of [M(L)ᵢ]^{m+} [symbol] Mⁿ⁺+iL (in the formula, M represents a metal element of Cd or Zn, L represents a ligand, and m, n, and i: positive numbers, respectively).

The reaction solution used in the CBD film formation apparatus according to the first through third aspects of the present invention is, for example, a reaction solution containing a metal (M) source of Cd or Zn and a sulfur source. Accordingly, it is possible to form a buffer layer of CdS, ZnS, Zn(S, O), or Zn(S, O, OH). As the sulfur source, a compound containing sulfur, for example, such as thiourea (CS(NH₂))₂ and thioacetamide (C₂H₅NS), may be used.

When a buffer layer of CdS is formed, a mixed solution of the sulfur source, a Cd compound (for example, cadmium sulfate, cadmium acetate, cadmium nitrate, hydrates thereof, and the like), and ammonia water or ammonium salt (for example, CH₃COONH₄, NH₄Cl, NH₄I, (NH₄) ₂SO₄, and the like) may be used as the reaction solution. When the buffer layer is composed of a layer of a Zn compound, such as ZnS, Zn(S, O) and Zn(S, O, OH), a mixed solution of the sulfur source, a Zn compound (for example, zinc sulfate, zinc acetate, zinc nitrate, hydrates thereof, and the like), and ammonia water or ammonium salt (similar to the aforementioned examples) may be used as the reaction solution.

Here, when a buffer layer composed of a layer of a Zn compound is formed, it is desirable that the reaction solution contains a citric acid compound (trisodium citrate and/or a hydrate thereof). When the reaction solution contains a citric acid compound, a complex is easily formed, and crystal growth by the CBD reaction is controlled in an excellent manner. Therefore, stable formation of a film is possible.

The CBD film formation apparatus according to the first through third aspects of the present invention (the buffer layer production apparatus in the third aspect) may be applied to any kind of substrate. However, the effect of the present invention is that even if the substrate contains an element that is dissolvable in a reaction solution for CBD, the element does not dissolve from the substrate. Therefore, such an effect is achievable when the substrate contains a metal in which a hydroxide ion and a complex ion are formable. More specifically, the present invention is effectively applicable to a substrate containing Al.

Specifically, it is desirable that the substrate is one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

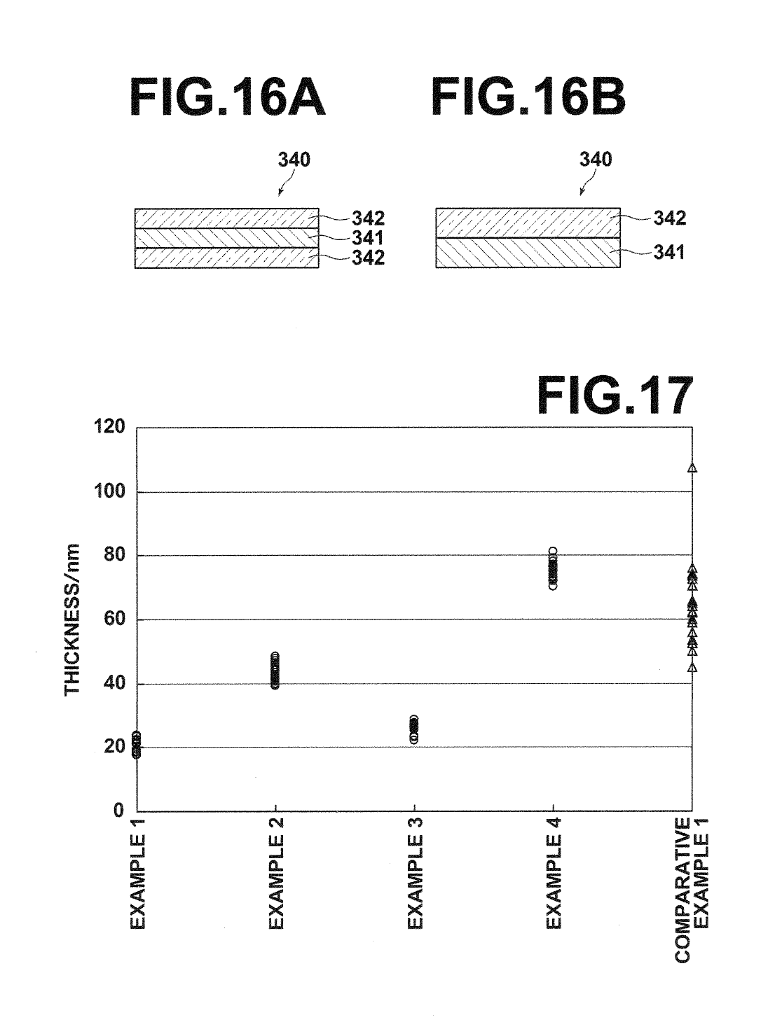

FIGS. 16A and 16B are schematic cross sections illustrating the structure of anodized substrates. As illustrated in FIG. 16A, anodized films 342 may be formed on both surfaces of the Al base material 341 in a substrate 340. Alternatively, as illustrated in FIG. 16B, an anodized film 342 may be formed on one of the surfaces of the Al base material 341. The anodized film 342 contains Al₂O₃ as a main component. It is desirable that the anodized films 342 are formed on both sides of the Al base material 341, as illustrated in FIG. 16A, to suppress a warp of the substrate caused by a difference in thermal expansion coefficients of Al and Al₂O₃, peeling of the film caused by the warp, and the like in a device production process.

The main component of the photoelectric conversion semiconductor layer is not particularly limited. However, at least one kind of compound semiconductor having chalcopyrite structure is desirable, because high conversion efficiency is achievable. Further, at least one kind of compound semiconductor composed of a group Ib element, a group IIIb element and a group VIb element is more desirable.

It is desirable that the main component of the photoelectric conversion semiconductor layer is at least one kind of compound semiconductor composed of at least one kind of Ib group element selected from a group consisting of Cu and Ag, at least one kind of IIIb group element selected from a group consisting of Al, Ga and In, and at least one kind of VIb group element selected from a group consisting of S, Se and Te. The aforementioned compound semiconductors are CuAlS₂, CuGaS₂, CuInS₂, CuAlSe₂, CuGaSe₂, AgAlS₂, AgGaS₂, AgInS₂, AgAlSe₂, AgGaSe₂, AgInSe₂, AgAlTe₂, AgGaTe₂, AgInTe₂, Cu (In, Al) Se₂, Cu(In, Ga) (S, Se)₂, Cu_{1-z}In₁₋ₓGaₓSe_{2-y}S_{y} (in the formula, 0≦x≦1, 0≦y≦2, 0≦z≦1) (CI(G)S), Ag(In, Ga)Se₂, Ag(In, Ga) (S, Se)₂, and the like. Alternatively, the compound semiconductors may be Cu₂ZnSnS₄, Cu₂ZnSnSe₄, Cu₂ZnSn (S, Se)₄, CdTe, (Cd, Zn)Te, and the like.

The thickness of the photoelectric conversion semiconductor layer is not particularly limited. It is desirable that the thickness is 1.0 μm to 3.0 μm, and it is particularly desirable that the thickness is 1.5 μm to 2.0 μm.

When a transparent conductive layer (for example, n-ZnO, such as ZnO: Al, or the like) and an upper electrode (Al, or the like) are formed on the buffer layer, the photoelectric conversion device is completed. The transparent conductive layer allows light to enter, and functions also as an electrode that is paired with the lower electrode, and through which a current generated in the photoelectric conversion semiconductor layer flows. The photoelectric conversion device is applicable to solar cells in a desirable manner. A cover glass, a protection film or the like may be attached to the photoelectric conversion device, if necessary, to produce the solar cells.

Next, the present invention will be described in more detail by using examples.

### Example of First Aspect

(Production of Substrate through Photoelectric Conversion Layer)

A two-layer clad material composed of stainless steel (SUS) having a thickness of 100 μm and an Al layer having a thickness of 30 μm was produced, by using a cold rolling method, by pressure-bonding stainless steel and high purity Al (the purity of Al:4N) together and by reducing the thicknesses. The produced material was used as a metal substrate. The metal substrate was cut to obtain a sheet the size of which is 30 cm×30 cm. An aluminum anodized film (AAO) the thickness of which is 10 μm was formed on the metal substrate. Further, a soda lime glass (SLG) layer the thickness of which is 0.2 μm and a Mo lower electrode the thickness of which is 0.8 μm were formed, by sputtering, on the aluminum anodized film. Further, a Cu(In_{0.7}Ga_{0.3})Se₂ layer the thickness of which is 1.8 μm was formed on this substrate by using a three-stage method, which is one of known methods for depositing a CIGS layer.

### (Preparation of Reaction Solution)

A reaction solution was prepared by adding components to water and by mixing them so that the concentration of ZnSO₄ is 0.03 M, and the concentration of thiourea is 0.05 M, and the concentration of trisodium citrate is 0.03 M, and the concentration of ammonia is 0.15 M.

### EXAMPLE 1

Only a sheet of prepared substrate was set at a left-end reaction bath part of the support-heat unit 3 in the CBD reaction apparatus illustrated in FIG. 1. The CBD reaction solution was heated at 90° C., and deposition of a buffer layer was carried out for 15 minutes.

### EXAMPLE 2

Deposition of a buffer layer was carried out in a similar manner to Example 1 except that the CBD reaction apparatus was changed to the one illustrated in FIG. 2.

### COMPARATIVE EXAMPLE 1

A prepared CBD reaction solution was put in a reaction vessel made of PFA, and a prepared substrate was put in the reaction vessel in such a manner that the substrate stands at a center of the reaction vessel. Further, deposition of a buffer layer was performed for 60 minutes.

### (Evaluation)

After deposition of the buffer layer in Examples 1 and 2 and Comparative Example 1, 2.5 mL of CBD reaction solution was diluted by filling up a volumetric flask of 25 mL to the mark of 25 mL (diluted ten times). Further, the concentration of Al was measured by using an SPS3000 ICP optical emission spectrometric apparatus (lower limit of quantitation: Al (<1 ppm)). Here, a measurement result was obtained by performing measurement twice for each sample, and by calculating an average of the obtained values.

Further, the surface of the deposited buffer layer and the cross section of the buffer layer were observed by SEM, and adhesion of colloidal particles was observed. Table 1 shows an evaluation result together with the reaction conditions and the like of Examples 1, 2 and Comparative Example 1:

TABLE 1

| | | | Comparative |
|---|---|---|---|
| | Example 1 | Example 2 | Example 1 |
| Reaction | FIG. 1 | FIG. 2 | Vessel made |
| Apparatus | | | of PFA |
| Substrate | Cu(In_{0.7}Ga_{0.3})Se₂/Mo/SLG/AAO/Al/SUS | | |
| through | | | |
| Photoelectric | | | |
| Conversion | | | |
| Semiconductor | | | |
| Layer | | | |
| Protection | Protected | Protected | None |
| of Back | | | |
| Surface and | | | |
| Edge Surface | | | |
| of Substrate | | | |
| Buffer Layer | 90 | 90 | 90 |
| Formation | | | |
| Temperature | | | |
| (T[° C.]) | | | |
| Buffer Layer | Zn (S, O) or | Zn (S, O) or | Zn (S, O) or |
| | (Zn (S, O, OH)) | (Zn (S, O, OH)) | (Zn (S, O, OH)) |
| Deposition | 15 | 15 | 60 |
| Time | | | |
| (minute) | | | |
| Adhesion of | None | Present | Present |
| Colloid | | | |
| Dissolution | None | None | 5 |
| of Substrate | | | |
| (Concentra- | | | |
| tion of Al: | | | |
| ppm) | | | |

As Table 1 clearly shows, the examples using the production apparatus according to the first aspect of the present invention could form a buffer layer without dissolving Al contained in the substrate. In contrast, in Comparative Example 1, in which the back surface and the edge surfaces of the substrate touched the reaction solution, dissolution of Al was confirmed. Further, in Example 1, in which the CBD film formation apparatus illustrated in FIG. 1 was used, adhesion of colloidal particles was not recognized. Therefore, a portion coated with the buffer layer produced by the CBD film formation apparatus illustrated in FIG. 1 can maintain high resistance. When the buffer layer is applied to solar cells, it is possible to improve the conversion efficiency of the solar cells.

### Example of Second Aspect

(Production of Substrate through Photoelectric Conversion Layer)

A two-layer clad material composed of stainless steel (SUS) having a thickness of 100 μm and an Al layer having a thickness of 30 μm was produced, by using a cold rolling method, by pressure-bonding high purity Al (the purity of Al:4N) to stainless steel having a width of 30 cm and a length of 90 m in the longitudinal direction, and by reducing the thickness. The produced material was used as a metal substrate. An aluminum anodized film (AAO) the thickness of which is 10 μm was formed on the metal substrate. Further, a soda lime glass (SLG) layer the thickness of which is 0.2 μm and a Mo lower electrode the thickness of which is 0.8 μm were formed, by sputtering, on the aluminum anodized film. Further, a Cu(In_{0.7}Ga_{0.3})Se₂ layer the thickness of which is 1.8 μm was formed on this substrate by using a three-stage method, which is one of known methods for depositing a CIGS layer.

### (Preparation of Reaction Solution)

A reaction solution was prepared by adding components to water and by mixing them so that the concentration of ZnSO₄ is 0.03 M, and the concentration of thiourea is 0.05 M, and the concentration of trisodium citrate is 0.03 M, and the concentration of ammonia is 0.15 M.

### EXAMPLE 1

The prepared long substrate was set in the CBD reaction apparatus illustrated in FIG. 1. The CBD reaction solution was heated at 90° C., and deposition of a buffer layer was carried out on the long substrate the total length of which is 90 m for 150 minutes in total.

### EXAMPLE 2

Deposition of a buffer layer was carried out in a similar manner to Example 1 except that the total time of deposition carried out on the long substrate the total length of which is 90 m was 600 minutes.

### COMPARATIVE EXAMPLE 1

Deposition of a buffer layer was carried out in a similar manner to Example 1 in the CBD reaction apparatus illustrated in FIG. 1 except that deposition of the buffer layer was carried out in a state in which the protection members were removed.

### (Evaluation)

After deposition of the buffer layer in Examples 1 and 2 and Comparative Example 1, 2.5 mL of CBD reaction solution was diluted by filling up a volumetric flask of 25 mL to the mark of 25 mL (diluted ten times). Further, the concentration of Al was measured by using an SPS3000 ICP optical emission spectrometric apparatus (lower limit of quantitation: Al (<1 ppm)). Here, a measurement result was obtained by performing measurement twice for each sample, and by calculating an average of the obtained values.

Table 2 shows an evaluation result together with the reaction conditions and the like of Examples 1, 2 and Comparative Example 1:

TABLE 2

| | | | Comparative |
|---|---|---|---|
| | Example 1 | Example 2 | Example 1 |
| Substrate | Cu(In_{0.7}Ga_{0.3})Se₂/Mo/SLG/AAO/Al/SUS | | |
| through | | | |
| Photoelectric | | | |
| Conversion | | | |
| Semiconductor | | | |
| Layer | | | |
| Protection | Protected | Protected | None |
| of Edge | | | |
| Surface of | | | |
| Substrate | | | |
| Drum Heating | Heated | Heated | None |
| Buffer Layer | 90 | 90 | 90 |
| Formation | | | |
| Temperature | | | |
| (T[° C.]) | | | |
| Buffer Layer | Zn (S, O) or | Zn (S, O) or | Zn (S, O) or |
| | (Zn (S, O, OH)) | (Zn (S, O, OH)) | (Zn (S, O, OH)) |
| Total | 150 | 600 | 150 |
| Deposition | | | |
| Time (minute) | | | |
| Adhesion of | None | Present | Present |
| Colloid | | | |
| Dissolution | None | None | 23 |
| of Substrate | | | |
| (Concentra- | | | |
| tion of Al: | | | |
| ppm) | | | |

As Table 2 clearly shows, the examples using the production apparatus according to the second aspect of the present invention could form a buffer layer without dissolving Al contained in the substrate. In contrast, in Comparative Example 1, in which the edge surfaces of the substrate touched the reaction solution, dissolution of Al was confirmed. Therefore, according to the CBD film formation apparatus of the second aspect of the present invention, even if the substrate contains an element that is dissolvable in the reaction solution for CBD, it is possible to form a film without dissolving such an element from the substrate.

### Example of Third Aspect

(Production of Substrate through Photoelectric Conversion Layer)

A two-layer clad material composed of stainless steel (SUS) having a thickness of 100 μm and an Al layer having a thickness of 30 μm was produced, by using a cold rolling method, by pressure-bonding stainless steel and high purity Al (the purity of Al:4N) together, and by reducing the thickness. The produced material was used as a metal substrate. The metal substrate was cut to obtain a sheet the size of which is 30 cm×30 cm. An aluminum anodized film (AAO) the thickness of which is 10 μm was formed on the metal substrate. Further, a soda lime glass (SLG) layer the thickness of which is 0.2 μm and a Mo lower electrode the thickness of which is 0.8 μm were formed, by sputtering, on the aluminum anodized film. Further, a Cu(In_{0.7}Ga_{0.3})Se₂ layer the thickness of which is 1.8 μm was formed on this substrate by using a three-stage method, which is one of known methods for depositing a CIGS layer.

### (Preparation of Reaction Solution)

A reaction solution was prepared by adding components to water and by mixing them so that the concentration of ZnSO₄ is 0.03 M, and the concentration of thiourea is 0.05 M, and the concentration of trisodium citrate is 0.03 M, and the concentration of ammonia is 0.15 M.

### EXAMPLE 1

Only one prepared substrate was set in the reaction bath illustrated in FIG. 13, and dummy substrates were mounted on the remaining three wall surfaces. The CBD reaction solution was heated at 90° C., and deposition of a buffer layer was carried out for 15 minutes. With respect to the obtained buffer layers, after performing FIB treatment on the cross sections, SEM observation was performed at accelerating voltage of 5 kV. Further, the thicknesses of the buffer layers were measured based on plural SEM images (data were obtained at 21 positions).

### EXAMPLE 2

Deposition of buffer layers was carried out in a similar manner to Example 1 except that the CBD reaction solution was stirred by a magnetic stirrer.

### EXAMPLE 3

Deposition of buffer layers was carried out in a similar manner to Example 1 except that the time period of deposition was changed to 30 minutes.

### Example 4

Deposition of buffer layers was carried out in a similar manner to Example 3 except that the CBD reaction solution was stirred by a magnetic stirrer.

### COMPARATIVE EXAMPLE 1

A prepared CBD reaction solution was put in a reaction vessel made of PFA, and a prepared substrate was put in the reaction vessel in such a manner that the substrates stands at a center of the reaction vessel. Further, deposition of a buffer layer was performed for 60 minutes.

### (Evaluation)

After deposition of the buffer layers in Examples 1 through 4 and Comparative Example 1, 2.5 mL of CBD reaction solution was diluted by filling up a volumetric flask of 25 mL to the mark of 25 mL (diluted ten times). Further, the concentration of Al was measured by using an SPS3000 ICP optical emission spectrometric apparatus (lower limit of quantitation: Al (<1 ppm)). Here, a measurement result was obtained by performing measurement twice for each sample, and by calculating an average of the obtained values.

Table 3 shows an evaluation result together with the reaction conditions and the like of Examples 1 through 4 and Comparative Example 1. Further, FIG. 17 illustrates a graph showing the distribution of the thicknesses of buffer layers in Examples 1 through 4 and Comparative Example 1.

TABLE 3

| | Example | Example | Example | Example | Comparative |
|---|---|---|---|---|---|
| | 1 | 2 | 3 | 4 | Example 1 |
| Substrate | Cu(In_{0.7}Ga_{0.3})Se₂/Mo/SLG/AAO/Al/SUS | | | | |
| through | | | | | |
| Photoelectric | | | | | |
| Conversion | | | | | |
| Semiconductor | | | | | |
| Layer | | | | | |
| Protection of | Protected | Protected | Protected | Protected | None |
| Back Surface | | | | | |
| and Edge | | | | | |
| Surface of | | | | | |
| Substrate | | | | | |
| Buffer Layer | 90 | 90 | 90 | 90 | 90 |
| Formation | | | | | |
| Temperature | | | | | |
| (T[° C.]) | | | | | |
| Buffer Layer | Zn (S, O) or | Zn (S, O) or | Zn (S, O) or | Zn (S, O) or | Zn (S, O) or |
| | (Zn (S, O, OH)) | (Zn (S, O, OH)) | (Zn (S, O, OH)) | (Zn (S, O, OH)) | (Zn (S, O, OH)) |
| Stir | None | Stirred | None | Stirred | None |
| Deposition Time | 15 | 15 | 30 | 30 | 60 |
| (minute) | | | | | |
| Average | 20.2 | 43.3 | 26.0 | 74.9 | 64.2 |
| Deposition | | | | | |
| Thickness (nm) | | | | | |
| Standard | 1.8 | 2.7 | 1.7 | 2.8 | 13.2 |
| Deviation of | | | | | |
| Thickness | | | | | |
| Dissolution of | None | None | None | None | 5 |
| Substrate | | | | | |
| (Concentration | | | | | |
| of Al: ppm) | | | | | |

As Table 3 clearly shows, the examples using the production apparatus according to the third aspect of the present invention could form a buffer layer without dissolving Al contained in the substrate. In contrast, in Comparative Example 1, in which the back surface and the edge surfaces of the substrate touched the reaction solution, dissolution of Al was confirmed. Further, as the standard deviation of thickness in Table 3 and the graph illustrated in FIG. 17 clearly show, an influence of a difference in temperature in the reaction bath is small. Therefore, it was possible to form a buffer layer the thickness of which is extremely even. Further, when the reaction solution is stirred, the deposition speed becomes higher, and reduction in the production time period is possible.

What is claimed is:

1. A CBD (Chemical Bath Deposition) film formation apparatus comprising:
a support-heat unit that supports and heats a substrate from the back side of the substrate;
a reaction bath having an opening for supplying a CBD reaction solution for forming a film onto a front surface of the substrate, which is supported by the support-heat unit; and
a reaction bath forward-backward drive unit that can press the opening onto the front surface of the substrate by moving the reaction bath toward the front surface of the substrate, which is supported by the support-heat unit, and that can detach the opening from the front surface of the substrate by moving the reaction bath away from the front surface of the substrate.

2. The CBD film formation apparatus, as defined in claim 1, wherein the support-heat unit supports the substrate from the upper side of the substrate, and
wherein the reaction bath is arranged on the lower side of the substrate, and moved toward the front surface of the substrate from the lower side of the substrate and away from the front surface of the substrate.

3. The CBD film formation apparatus, as defined in claim 2, wherein the reaction bath includes a reaction solution supply channel for supplying the reaction solution into the reaction bath and a reaction solution discharge channel for discharging the reaction solution in the reaction bath.

4. The CBD film formation apparatus, as defined in claim 3, wherein the substrate is a flexible substrate, and the apparatus comprising:
a roll core on which the flexible substrate is wound; and
a substrate conveyance unit that supplies the substrate to the support-heat unit by intermittently drawing the substrate from a substrate roll formed by winding the flexible substrate on the roll core.

5. The CBD film formation apparatus, as defined in claim 4, wherein a plurality of reaction baths are provided, and
wherein the plurality of reaction baths are simultaneously movable toward the substrate and away from the substrate.

6. The CBD film formation apparatus, as defined in claim 1, wherein the substrate contains a metal that can form a hydroxide ion and a complex ion.

7. The CBD film formation apparatus, as defined in claim 6, wherein the substrate is one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

8. A method for producing a buffer layer by using a CBD method in a photoelectric conversion device having a layered structure including a lower electrode, a photoelectric conversion semiconductor layer that generates an electric current by absorption of light, the buffer layer, and a transparent conductive layer on a substrate, the method for producing the buffer layer comprising the steps of:
supplying the substrate to a support-heat unit that supports and heats the substrate from the back side of the substrate, and heating the substrate from the back side of the substrate; and
moving, with respect to the heated substrate, a reaction bath having an opening for supplying a CBD reaction solution for forming the buffer layer toward a front surface of the substrate, which is supported by the support-heat unit, and pressing the opening onto the front surface of the substrate to deposit the buffer layer on a surface of the photoelectric conversion semiconductor layer provided on the substrate.

9. A method for producing a photoelectric conversion device having a layered structure including a lower electrode, a photoelectric conversion semiconductor layer that generates an electric current by absorption of light, a buffer layer, and a transparent conductive layer on a substrate, wherein the buffer layer is produced by using a CBD method, and the method for producing the photoelectric conversion device comprising the steps of:
supplying the substrate to a support-heat unit that supports and heats the substrate from the back side of the substrate, and heating the substrate from the back side of the substrate; and
moving, with respect to the heated substrate, a reaction bath having an opening for supplying a CBD reaction solution for forming the buffer layer toward a front surface of the substrate, which is supported by the support-heat unit, and pressing the opening onto the front surface of the substrate to deposit the buffer layer on a surface of the photoelectric conversion semiconductor layer provided on the substrate.

10. A CBD film formation apparatus comprising:
a drum that supports a long substrate in close contact with the long substrate;
a reaction bath filled with a CBD reaction solution for immersing therein a part of the drum, which supports the long substrate in close contact with the long substrate;
protection members that protect edges on lateral direction sides of the long substrate, which is supported by the drum in close contact with the drum, and portions of the drum that are not in close contact with the long substrate from the CBD reaction solution by overlapping with the edges on the lateral direction side and the portions of the drum; and
a drive unit that makes the long substrate, which is in close contact with the drum, and the protection members run together in the CBD reaction solution in such a manner to be matched with the peripheral velocity of the drum.

11. The CBD film formation apparatus, as defined in claim 10, wherein the drum includes a heating means that heats the long substrate, which is supported by the drum in close contact with the drum.

12. The CBD film formation apparatus, as defined in claim 11, wherein the drum can magnetically support the long substrate in close contact with the long substrate.

13. The CBD film formation apparatus, as defined in claim 12, wherein the surface of the CBD reaction solution in the reaction bath is located at a lower position than positions at which the long substrate and the protection members overlapping with the long substrate start contacting with each other.

14. The CBD film formation apparatus, as defined in claim 10, wherein the long substrate contains a metal that can form a hydroxide ion and a complex ion.

15. The CBD film formation apparatus, as defined in claim 14, wherein the long substrate is one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

16. The CBD film formation apparatus, as defined in claim 10, wherein the long substrate includes a lower electrode and a photoelectric conversion semiconductor layer that generates an electric current by absorption of light.

17. A method for producing a photoelectric conversion device having a layered structure including a buffer layer and a transparent conductive layer on a photoelectric conversion semiconductor layer of a long substrate including a lower electrode and the photoelectric conversion semiconductor layer that generates an electric current by absorption of light, wherein the buffer layer is formed by making a drum support the long substrate in such a manner that the drum is in close contact with the long substrate and that a photoelectric conversion semiconductor layer side surface of the long substrate is positioned on the front surface side of the long substrate, and by making protection members overlap with edges on lateral direction sides of the long substrate, which is supported by the drum in close contact with the drum, and portions of the drum that is not in close contact with the long substrate, and by immersing, in a reaction solution for forming the buffer layer in a reaction bath, a part of the drum, which supports the long substrate in close contact with the long substrate.

18. A method for producing a buffer layer by using a CBD method in a photoelectric conversion device having a layered structure including a lower electrode, a photoelectric conversion semiconductor layer that generates an electric current by absorption of light, the buffer layer, and a transparent conductive layer on a substrate, the method for producing the buffer layer comprising the steps of:
fixing the substrate at an opening that is provided on a wall of a reaction bath for CBD, and the size of the opening being less than the size of the substrate, in such a manner to cover the whole opening with the substrate from the outside of the reaction bath; and
depositing the buffer layer in a region of a surface of the photoelectric conversion semiconductor layer provided on the substrate, and the region facing the opening.

19. The method for producing a buffer layer, as defined in claim 18, wherein the substrate is heated from the back side of the substrate.

20. The method for producing a buffer layer, as defined in claim 19, wherein the reaction solution is stirred.

21. The method for producing a buffer layer, as defined in claim 18, wherein the reaction solution contains a metal source of Cd or Zn and a sulfur source.

22. A buffer layer production apparatus that forms, on a photoelectric conversion semiconductor layer formed on a substrate, a buffer layer by using a CBD method, the apparatus comprising:
a reaction bath that can store a reaction solution for CBD to form the buffer layer;
an opening formed on a wall of the reaction bath, and the size of the opening being less than the size of the substrate; and
a holding unit that can hold the substrate on an outer surface of the wall of the reaction bath at a position corresponding to the opening in such a manner to cover the whole opening with the substrate.

23. The buffer layer production apparatus, as defined in claim 22, further comprising:
a heating means that can heat the substrate from the back side of the substrate.

24. The buffer layer production apparatus, as defined in claim 23, wherein the reaction bath is made of a material that is both alkali-resistant and acid-resistant.

25. The buffer layer production apparatus, as defined in claim 24, wherein the reaction bath includes a stirring means that stirs the reaction solution.

26. The buffer layer production apparatus, as defined in claim 22, wherein the substrate contains a metal that can form a hydroxide ion and a complex ion.

27. The buffer layer production apparatus, as defined in claim 26, wherein the substrate is one of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

28. A method for producing a photoelectric conversion device having a layered structure including a lower electrode, a photoelectric conversion semiconductor layer that generates an electric current by absorption of light, a buffer layer, and a transparent conductive layer on a substrate, wherein the buffer layer is produced by using a CBD method, the method for producing the photoelectric conversion device comprising the steps of:
fixing the substrate at an opening that is provided on a wall of a reaction bath for CBD, and the size of the opening being less than the size of the substrate, in such a manner to cover the whole opening from the outside of the reaction bath; and
depositing the buffer layer in a region of a surface of the photoelectric conversion semiconductor layer provided on the substrate, and the region facing the opening.
